(19) United States
(12) Patent Application Publication
(10) Pub. No.: US 2026/0013174 A1
(43) Pub. Date: Jan. 8, 2026

(54) SUPERJUNCTION POWER SEMICONDUCTOR DEVICE AND METHOD FOR MANUFACTURING A SUPERJUNCTION POWER SEMICONDUCTOR DEVICE

(71) Applicant: Hitachi Energy Ltd, Zürich (CH)

(72) Inventors: Stephan WIRTHS, Thalwil (CH); Lars KNOLL, Hägglingen (CH)

(21) Appl. No.: 19/123,901

(22) PCT Filed: Nov. 8, 2022
(86) PCT No.: PCT/EP2022/081102

§ 371 Date: Apr. 24, 2025

(51) Int. Cl. H10D 30/66; H10D 30/01

(52) U.S. Cl. CPC H10D 30/66; H10D 30/0291

(57) ABSTRACT

A superjunction power semiconductor device comprising a substrate, a plurality of core structures and a plurality of annular shell structures. Each core structure has a cylindrical shape extending in a direction perpendicular to a main surface of the substrate and comprising a first semiconductor material of a first conductivity type. Each shell structure surrounds one of the core structures on its outside and comprises a second semiconductor material of a second conductivity type.

The present disclosure generally relates to semiconductor devices and methods for their manufacturing, and in particular to a novel approach comprising selectively grown superjunction nanostructures for power semiconductor devices.

Wide bandgap (WBG) semiconductor materials, such as silicon carbide (SiC), have advantageous properties, including a high critical electric field and electron mobility or high frequency switching. Accordingly, they yield a much larger Baliga figure-of-merit (BFOM) compared to commonly used semiconductor materials, such as silicon, making them a good option for power semiconductor devices, such as power MISFETS. These advantages enable several applications for energy efficiency and electric transportation.

Nowadays most commercially available power SiC metal-oxide-semiconductor field-effect transistors (MOSFETs) are based on cell designs with planar channels aligned to the Silicon (Si) face, i.e. at the SiC (0001) wafer surface. However, the increase of current densities in such switches is hampered due to an increase of the junction-FET (JFET) resistance with down-scaling of the injectors as well as due to the low inversion channel mobility.

As an alternative approach, trench MOSFETs comprising a dry-etched U-shape channel enable the achievement of low ON resistances due to the lack of a JFET region and a high cell density. Especially for SiC channel devices, the trench MOSFET architecture allows optimization of carrier mobility by designing the channel with respect to different crystallographic planes and increasing gate dielectric control. Despite making use of different crystallographic planes for the carrier transport, the trench pitch and cell width of known trench MOSFET devices are still rather large when using conventional manufacturing techniques. This in turn prohibits higher cell densities and, thus, improved current densities of the finished semiconductor power devices. Moreover, monocrystalline SiC wafers are relatively expensive, further hindering the widespread adoption of the above approaches on a large scale.

Accordingly, novel processing methods and device architectures are desirable, which enable higher currents on smaller areas, i.e. improved current densities. Moreover, it would be desirable to integrate such architectures in a broad range of widely available, competitively priced substrates such as Si, gallium nitride (GaN), 4H-SiC or polycrystalline SiC substrates.

Embodiments of the disclosure relate to superjunction power semiconductor devices, comprising a substrate, a plurality of core structures, and a plurality of annular shell structures, as well as methods for manufacturing a superjunction power semiconductor device.

According to a first aspect of the disclosure, a superjunction power semiconductor device is provided. The device comprises:
a substrate;
a plurality of core structures, each core structure having a cylindrical shape extending in a direction perpendicular a main surface of the substrate and comprising a first semiconductor material of a first conductivity type; and
a plurality of annular shell structures, each shell structure surrounding one of the core structures on its outside and comprising a second semiconductor material of a second conductivity type.

The proposed device concept is based on vertically oriented, preferably very narrow superjunction structures, which can be selectively grown from suitable semiconductor materials, including WBG semiconductor materials. Due to their small size and vertical orientation, these structures are also referred to a nanowires or nanopillars. Such superjunction structures go far beyond conventional trench designs and allow improved pitch scaling, i.e. higher currents on smaller areas, and integration on a variety of widely available substrates due to the proposed selective growth technology.

According to at least one implementation, the device further comprises a dielectric layer arranged on the main surface of the substrate. The plurality of shell structures surrounding the plurality of core structures are embedded in the dielectric layer. The embedding of the superjunction structures in a dielectric layer has a number of advantages compared with conventional superjunction structures formed directly in a bulk semiconductor material. Firstly, it reduces the amount of semiconductor material required to implement the device. Secondly, the individual superjunction structures are electrically insulated from one another. Thirdly, at least parts of the dielectric layer may also serve as growth templates for creating the core structures and/or annular shell structures, and or as supporting structure for carrying terminal contacts.

According to at least one implementation, the dielectric layer comprises at least a first sublayer and a second sublayer. The first sublayer is arranged between the substrate and the second sublayer and comprises a plurality of passages there between. The second sublayer comprises at least a lower part of each one of the plurality of shell structures. The device further comprises a plurality of plug structures, each plug structure comprising a third semiconductor material of the second conductivity type and arranged in the area of one of the passages so as to contact the main surface of the substrate and the respective one of the shell structures. The above structure enables an electrical contact between the shell structures and the substrate of the device. At the same time, the passage may be used to implement a defect filter.

According to at least one implementation, the device further comprises a plurality of channel areas formed in each one of the shell structures, each channel area comprising a fourth semiconductor material of the first conductivity type and being arranged in a control layer of the device. The device further comprises at least one gate structure arranged in the control layer, the at least one gate structure being insulated from and surrounding at least a part of each one of the shell structures. The above device comprises a so-called gate-all around-structure, which provides a very high electric field control of a channel area. The channel area can be used to implement a variety of known power semiconductor switching cells, such as MOSFETs.

According to different implementations, the substrate may be one of a Si, SiC or GaN semiconductor substrate. The first semiconductor material may comprise a p-type semiconductor material, in particular Si, or a p-type WBG semiconductor material, in particular SiC, GaN or gallium oxide (GaₓO_{y}), in particular gallium trioxide (Ga₂O₃). The second semiconductor material may comprise an n-type semiconductor material, in particular Si, an n-type WBG semiconductor material, in particular SiC, GaN, GaₓO_{y}, in particular Ga₂O₃, or an n-type diamond.

The above substrate materials are widely available. At least some of them are considerably cheaper than monocrystalline SiC wafers. Moreover, the specific semiconductor materials used for the core end cell structures are also widely available and can be processed with conventional semiconductor processing equipment.

According to different implementations, the core structures and/or the shell structures may extend over a length of 1 to 100 μm in the direction perpendicular to the main surface of the substrate, in particular over a length of 3 to 15 μm. The core structures may have a diameter of 25 nm to 5 μm, in particular 0.1 to 5 μm. The annular cell structures may have a thickness of 0.1 to 5 μm. The plurality of core structures may be arranged in a regular pattern, in particular in an array structure, with a pitch distance of less than 1 μm and/or in the range of 1.1 to 2.5 times the total diameter of one of the core structures surrounded by one of the shell structures.

The above dimensions and configurations are suitable for manufacturing high density, high voltage and/or high current semiconductor power switching devices. For example, lengths of 1 to 100 μm are suitable for implementing semiconductor switching devices with a switching voltage of 1.2 to 3.3 kV at a device level. Core structures having a diameter in the order of 25 nm are particularly suitable for hetero-epitaxy, larger diameters are suitable for higher currents and/or homo-epitaxy. The current density is also affected by the dopant concentration of the used semiconductor materials. Preferably, the wall thickness of the shell structures may be similar to the diameter of the core structures and/or the diameter of any plug structures, e.g. have an aspect ratio of 1:1.

In at least one embodiment, the plurality of core structures and/or shell structures are electrically connected in parallel to form a multi-cell field-effect transistor (FET), in particular a metal-insulator-semiconductor field-effect transistor (MISFET), a MOSFET, an insulated gate bipolar transistor (IGBT) and/or a JFET.

According to a second aspect of the present disclosure, a method for manufacturing a superjunction power semiconductor device is provided. The method comprises:
providing a growth substrate;
providing a plurality of vertical growth masks on the growth substrate;
selectively growing a first semiconductor material in the plurality of vertical growth masks to form a corresponding plurality of core structures in a direction perpendicular to a main surface of the growth substrate;
at least partially removing the plurality of vertical growth masks thereby exposing vertical surfaces of the plurality of core structures; and
selectively growing a second semiconductor material on the vertical surfaces of the plurality of core structures to form a corresponding plurality of shell structures surrounding the respective core structures.

Among others, the above method steps enable the manufacturing of core-shell superjunction structures as detailed above with regard to the first aspect, for example for implementing nanowire based superjunction power MOSFETs.

Instead of processing devices in a conventional top-down manner as used, for example, for the manufacturing of conventional trench gate MOSFETs, the disclosed manufacturing method is based on a bottom-up approach based on selective epitaxy. This in turn enables the advantageous use of materials in the formation of high density power devices as detailed above with regard to the first aspect.

The plurality of vertical growth masks may be formed in a two-step process. In at least one implementation, a growth seed mask layer with a plurality of first openings corresponding to a pitch distance between the plurality of core structures is formed first. Thereafter, a core structure mask layer with a plurality of second openings is formed, each second opening being arranged in an area corresponding to the respective first opening and being wider than the respective first opening. Such a two-layer structure enables the implementation of a defect filter for a later selective growth phase. Moreover, it allows the partial removal of only an upper part of the vertical growth mask, e.g. by using different materials for the sublayers and selective etching.

Similarly, the plurality of core structures may also be formed in a two-step process. In at least one implementation, in a first phase, a plurality of plug structures is formed by selectively growing a third semiconductor material comprising impurities of a first conductivity type, in particular n-type SiC, directly on the growth substrate in the plurality of vertical growth masks. Thereafter, either as a separate step or in a continuous vertical growth process with a changed dopant profile, a main portion of the plurality of core structures is formed by selectively growing the first semiconductor material comprising impurities of a second conductivity type, in particular p-type SiC, in the plurality of vertical growth masks.

In at least one implementation, forming of the plurality of shell structures comprises covering a top surface of the plurality of core structures with a growth-inhibiting material, in particular one of silicon dioxide (SiO₂), silicon nitride (SiN) or aluminum trioxide (Al₂O₃); removing an upper part of the plurality of vertical growth masks, in particular the core structure mask, such that a remaining, lower part of the plurality of vertical growth masks, in particular the growth seed mask, covers the growth substrate; and thereafter, forming the plurality of shell structures by selectively growing the second semiconductor material comprising impurities of the first conductivity type, in particular n-type SiC in a radial direction. The above steps enable a controlled, radial growth of the shell structures.

The present disclosure comprises several aspects of a novel architecture for high density semiconductor devices, in particular a superjunction power semiconductor devices. Every feature described with respect to one of the aspects is also disclosed herein with respect to other aspects, even if the respective feature is not explicitly mentioned in the context of the specific aspect.

The accompanying figures are included to provide a further understanding. In the figures, elements of the same structure and/or functionality may be referenced by the same reference signs, even if they are part of different embodiments and/or have a different configuration. It is to be understood that the embodiments shown in the figures are illustrative representations and are not necessarily drawn to scale.

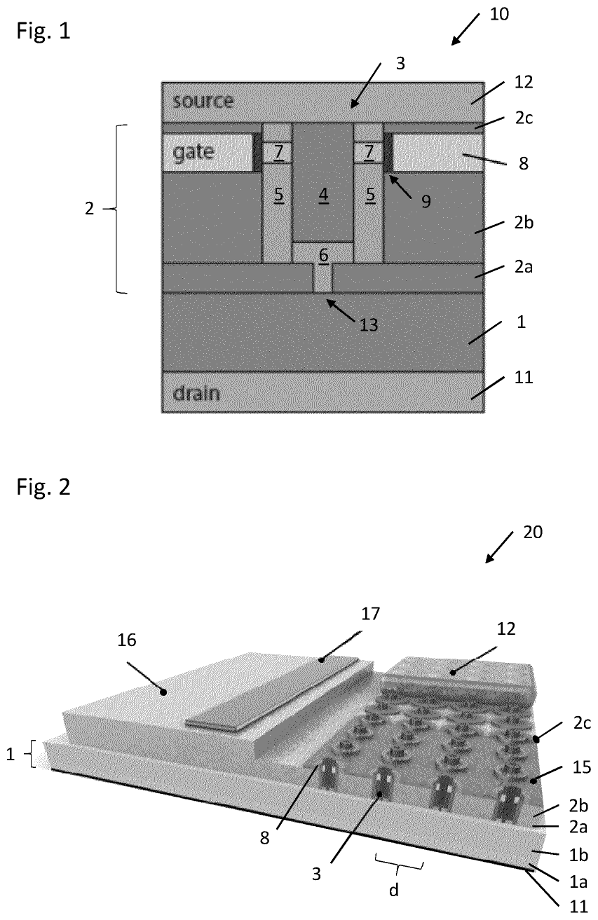

FIG. 1 is a schematic cross-section through a single cell of a power semiconductor switching device.

FIG. 2 is a perspective view of a power semiconductor device comprising a plurality of nanopillars.

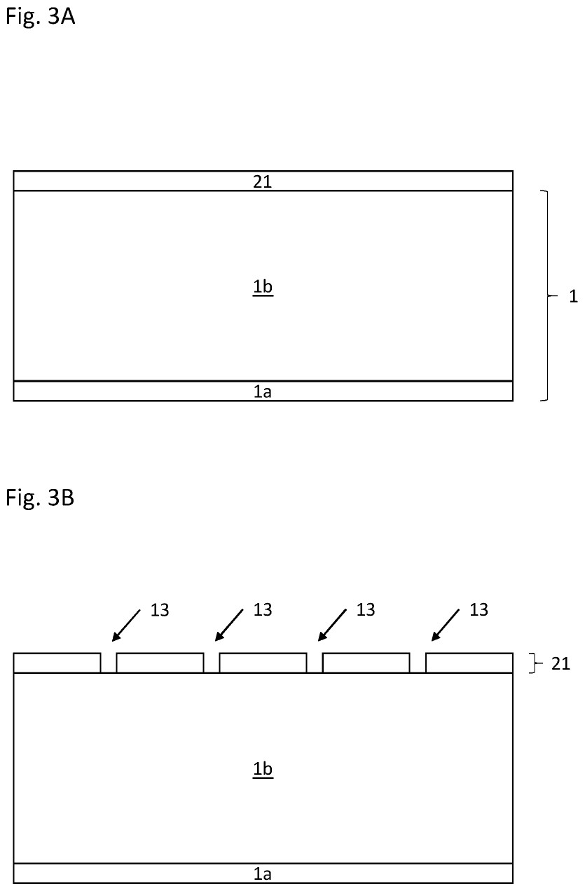

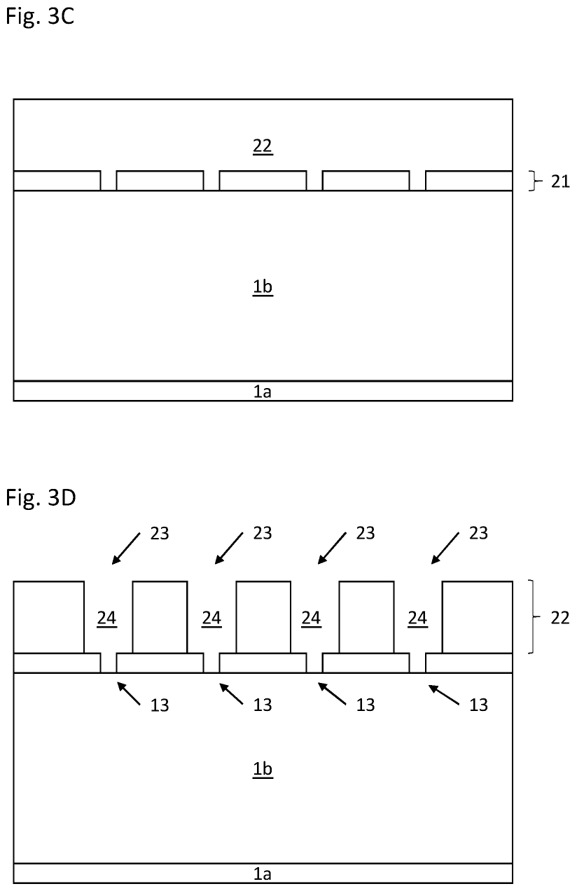

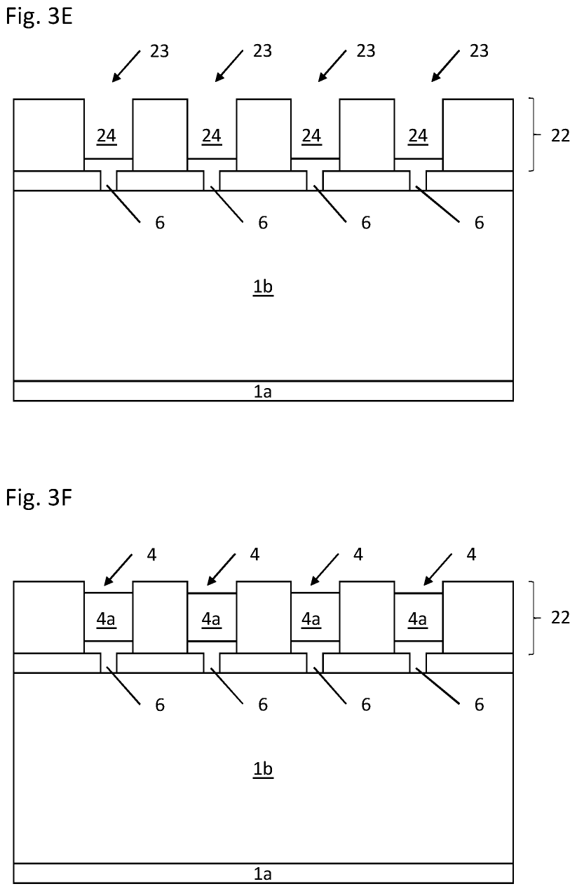

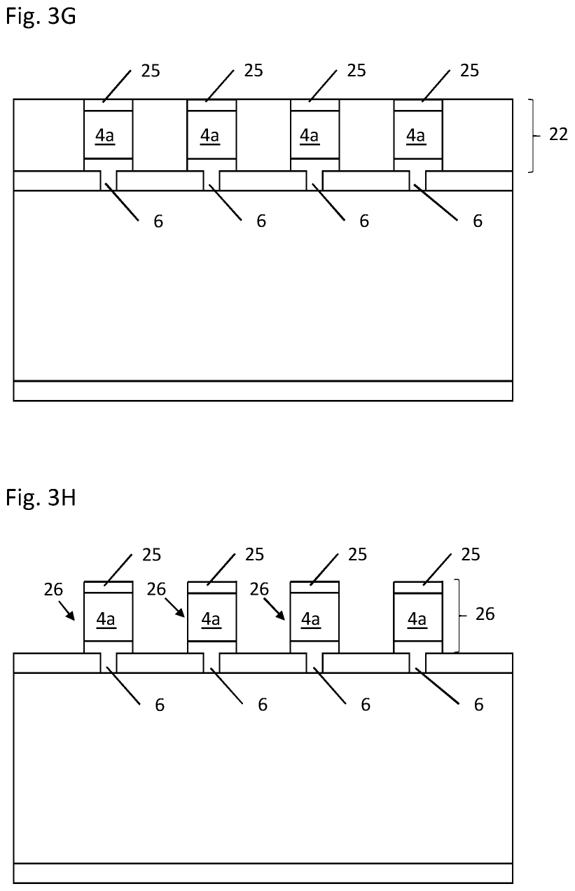

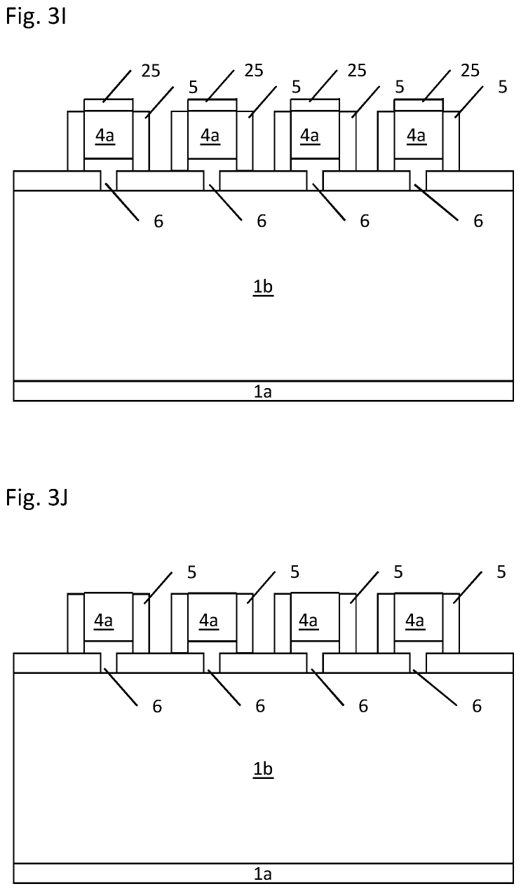

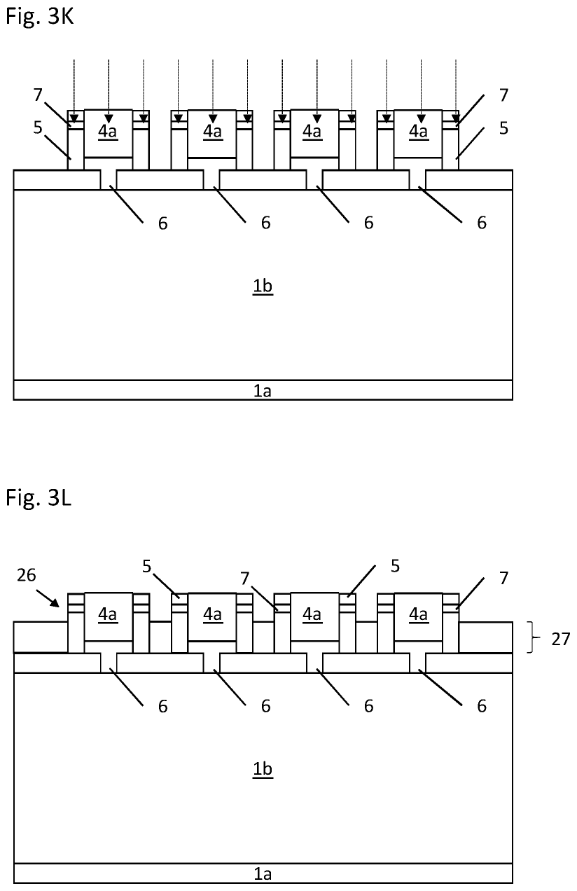

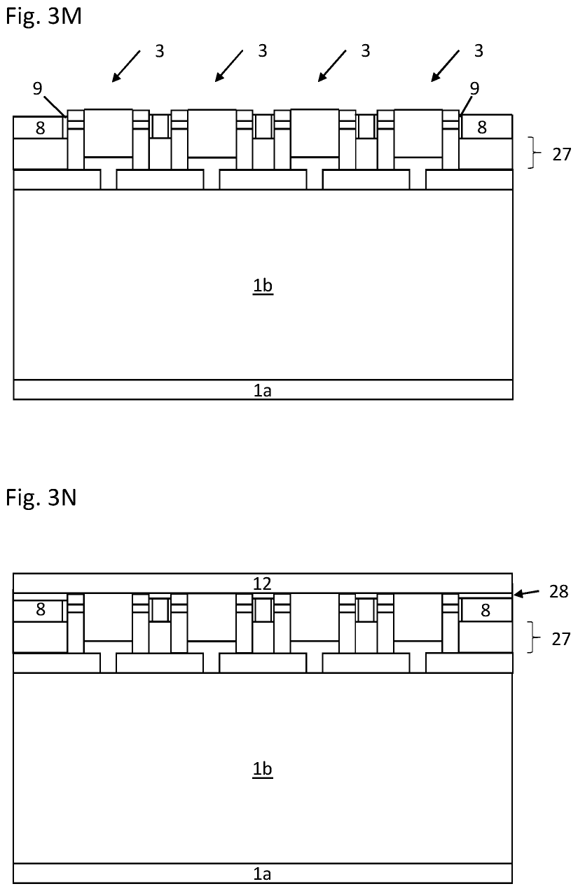

FIGS. 3A to 3N show various stages of manufacturing a power semiconductor device.

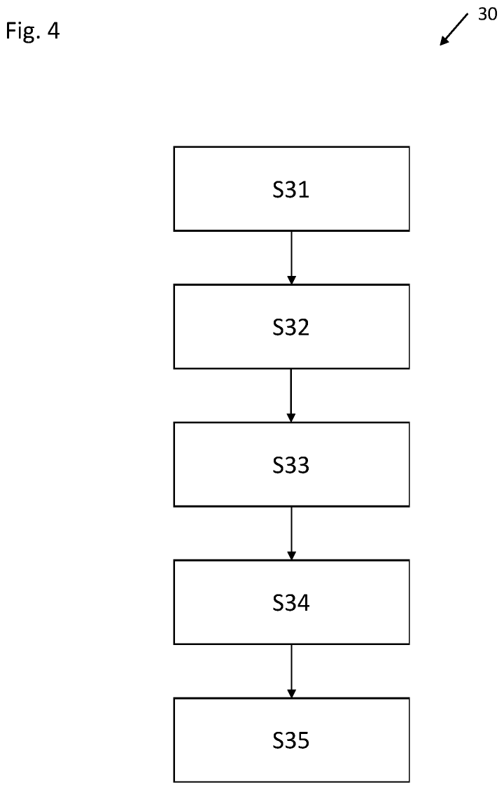

FIG. 4 shows, in the form of a flowchart, steps of a method for manufacturing a superjunction power semiconductor device.

FIG. 1 shows a cross-section through a cell 10 of a power semiconductor device or similar semiconductor device. A complete semiconductor device may typically comprises a relatively large number of similar cells electrically connected in parallel to achieve a desired function, including a desired current rating. However, for representational simplicity, only a single cell 10 is shown in FIG. 1 and described below.

The cell 10 comprises a substrate 1 which acts as a carrier substrate and also provides an electrical bottom contact as described later.

A dielectric layer 2 is arranged on an upper main surface of the substrate 1. The dielectric layer 2 may be formed of a SiO₂ or any other suitable insulating material. In this described embodiment, the dielectric layer 2 comprises a number of sublayers 2a to 2c as described later.

A superjunction structure 3 is embedded in the dielectric layer 2. The superjunction structure 3 comprises a core structure 4 and a shell structure 5, the latter surrounding the former on its outside. In the described embodiment, the core structure 4 has a cylinder shape, which is surrounded by an annular shell structure. However, in other embodiments, elongated, fin-shaped or stripe-shaped core structures 4 may be surrounded by corresponding shell structures. In the case that superjunction structure 3 is essentially cylindrical, it is also referred to as nanowires or nanopillars.

The core structure 4 is made of a first semiconductor material, in particular a WBG semiconductor material of a first conductivity type, such as p-type SiC. The shell structure 5 is made of a second semiconductor material of a different, second conductivity type, such as n-type SiC. Preferably, the majority charge carriers of the superjunction structure 3 balance each other.

The superjunction structure 3 further comprises a plug structure 6 at the lower end of the core structure 4. The plug structure 6 is made of a third semiconductor material of the second conductivity type. For example, the second and the third semiconductor material may be the same. The plug structure 6 electrically connects material of the shell structure 5 with the material of the substrate 1. For this purpose, a relatively narrow passage or opening 13 is formed in the lowest sublayer 2a of the dielectric layer 2. The opening 13 may also serve as a defect filter for the semiconductor material of the superjunction structure 3 during a growth phase as described later.

The superjunction structure 3 further comprises a channel area 7. The channel area 7 forms part of the shell structure 5. In the embodiment shown in FIG. 1, the channel area 7 is arranged in an upper part of the annular shell structure 5. As the channel area 7 can be used to control the flow of a current through the superjunction structure 3, the plane comprising channel area 7 is also referred to as control layer. The channel area 7 may have a thickness of 100 to 1000 nm. It may be formed by implanting a suitable dopant species, such as Al or B, into the upper part of the shell structure 5, for example to form a p-type area within an n-type semiconductor material of the shell structure 5. This may be achieved, for example, by ion implantation.

Conductivity of the channel area 7 is controlled by a surrounding gate structure 8. The gate structure 8 should overlap the channel area 7 on both sides. It may have a thickness of 200 to 1500 nm. In the embodiment shown, the gate structure 8 is buried in the dielectric layer 2. In particular, it is arranged between its two upper sublayers 2b and 2c. The gate structure 8 is electrically insulated by a relatively thin gate insulation 9 from the shell structure 5 comprising the channel area 7. For example, the gate insulation 9 may be formed by a film created by selective oxidation or deposition of an insulating material.

In order to contact the respective upper and lower ends of the superjunction structure 3, a drain electrode 11 is formed on a lower, second main surface of the substrate 1. In addition, a source electrode 12 is formed on the upper surface of the cell 10, comprising the upper surface of the topmost sublayer 2c of the dielectric layer 2 and the upper end of the superjunction structure 3 itself.

FIG. 2 shows a perspective view of a power semiconductor device 20 comprising a plurality of switching cells, such as the cell 10 described above with regard to FIG. 1. The switching cells are arranged in a regular pattern, in particular in an array structure with a grid or pitch distance d. In the described embodiment, the pitch distance may be around 1 um or smaller. Each cell comprises a superjunction structure 3 as detailed above. As discussed earlier, these take the form of a nanowires or nanopillars. To achieve high current densities, the pitch distance d may be chosen to be only marginally larger than the total diameter of the respective superjunction structure 3, e.g. have an aspect ratio of 1.1:1 to 2.5:1.

As can be seen in the front part of FIG. 2, a single, cylindrical gate structure 8 surrounds the channel area of each one of the superjunction structures 3. These so-called gate all-around structures 8 are interconnected by a metal layer 15. As detailed above, the gate all-around structure 8 is embedded between a sublayer 2b and a sublayer 2c formed from a dielectric material. In the depicted embodiment the metal layer 15 is thinner than the vertical thickness of the gate all-around structures 8. However, it may also have the same thickness, resulting essentially in a homogenous metal layer 15 acting as common gate structure 8 for all superjunction structures 3.

In the embodiment shown in FIG. 2, the upper ends of the superjunction structure 3 extend slightly over the top surface of the upmost sublayer 2c of the dielectric material. These ends are embedded directly into the metal material of a source electrode 12 formed thereon. Outside the array of superjunction structures 3, the dielectric material is even thicker and forms a termination area 16. On the upper surface of the termination area 16, a gate runner 17 is formed that is used as an external contact for the metal layer 15 and gate structures 8.

FIG. 2 further shows that the substrate 1 may comprise multiple sublayers. In the embodiment shown, a lower sublayer 1a may be formed by a wafer material, such as a silicon wafer. On its upper surface, an epitaxially grown layer forms a second, upper sublayer 1b. For example, polycrystalline SiC may be grown on the lower sublayer 1a as a seed material for growing the superjunction structures 3. In this case, the upper sublayer 1b filters out growth defects. In other embodiments, the upper sublayer 1b may itself form part of the finished semiconductor device 20. For example, the upper sublayer 1b may act as part of a drift layer. In yet other embodiments, the upper sublayer 1b may be omitted completely.

FIGS. 3A to 3N show various stages of manufacturing a superjunction semiconductor device, such as the superjunction power semiconductor device 20 shown in FIG. 2.

In a first stage shown in FIG. 3A, a substrate 1 is provided. As detailed above, the substrate 1 itself comprises two sublayers 1a and 1b. In the described embodiment, the first sublayer 1a is a silicon wafer. The sublayer 1b is an epitaxially grown silicon carbide layer. The substrate 1 is covered with a first dielectric layer 21. As shown in FIG. 1, the first dielectric layer 21 covers the upper surface of the sublayer 1b of the substrate 1. The first dielectric layer 21 may essentially consist of silicon oxide, SiOₓ, in particular SiO₂, silicon nitride, SiN, or Al₂O₃.

As shown in FIG. 3B, parts of the first dielectric layer 21 may be removed to form a number of openings 13. The openings 13 may be formed as regular intervals to form an array or other regular structure on the upper surface of the substrate 1. Such openings 13 may be formed, for example, using conventional lithography. Alternatively, dielectric material may be deposited only in the areas between the intended openings 13, e.g. using an appropriate selective deposition method. The material of the underneath substrate 1 or its uppermost sublayer 1b serves as a growth seed. In the described embodiment, the openings 13 may have a cross-section of 25 nm. A passage of this diameter effectively serves as a defect filter for selectively growing the core structures on substrate comprising a different semiconductor material and/or crystallographic configuration, e.g. for growing a SiC superjunction structure on a Si wafer using hetero-epitaxy. Accordingly, the first dielectric layer 21 is also referred to as growth seed mask layer. In case homo-epitaxy is used, e.g. for growing a SiC superjunction structure on a SiC wafer or epilayer, the opening 13 may be wider and can, for example, correspond in diameter to the diameter of the core structures 4 formed later.

FIG. 3C shows a further stage of the manufacturing process. At this stage, the upper surface of the device under manufacturing has been covered with dielectric material to form a second dielectric layer 22. The second dielectric layer 22 serves to form the growth mask for the actual core structures and is therefore also referred to as core structure mask layer. The second dielectric layer 22 may essentially consist of SiOₓ, in particular SiO₂, SiN or Al₂O₃. In case selective etching is employed later, the material of the first dielectric layer 21 and the second dielectric layer may differ. The second dielectric layer 22 may be planarized using generally known semiconductor processing methods.

FIG. 3D shows the situation after the material of the second dielectric layer 22 has been structured. This may be achieved, for example, using conventional lithography and selective etching. As can be seen in FIG. 3D, a number of hollow, vertical growth templates or masks 23 are formed. The vertical growth masks 23 comprise the openings 13 in the first dielectric layer 21 as well as a wider openings 24 in the second dielectric layer 22. The vertical growth masks 23 are used to selectively grow a suitable semiconductor material, such as a WBG semiconductor material, which will later form the core structures 4.

In a first selective growth phase shown in FIG. 3E, plug structures 6 are formed by selective area epitaxy. This can be achieved, among others, by selectively growing, i.e. depositing, semiconductor materials only inside the vertical growth masks 23, whereas growth is inhibited in other areas covered by the material of the growth templates, i.e. the first dielectric layer 21 and second dielectric layer 22.

As shown, the plug structures 6 are grown within the opening 13 of the first dielectric layer 21 as well as a bottom part of openings 24 of the second dielectric layer 22. In the described embodiment, the plug structures 6 are formed by depositing an n-type SiC material.

Thereafter, the remainder of the core structures 4 is grown on the upper end of the plug structures 6. Growth of the main portions 4a of the core structures 4 may be implemented as a separate selective growth step or may be performed in a continuous selective growth phase with a modified dopant profile. In the described embodiment, a p-type semiconductor material is selectively grown to form the main portions 4a of the core structure 4. This finished core structures 4 are shown in FIG. 3F.

In the situation shown in FIG. 3G, the upper ends of the core structures 4 have been capped with capping elements 25. In the described embodiment, this is achieved by filing the remaining part of the openings 24 with in the second dielectric layer 22 with a dielectric material. The capping element 25 may be formed by depositing a growth inhibiting material, such as SiO₂, SiN or Al₂O₃.

FIG. 3H shows the device under manufacturing after the remaining material of the second dielectric layer 22 has been removed. This can be achieved, for example, by a selective etching process, and exposes vertical surfaces 26 on each one of the previously formed core structures 4.

In a subsequent stage shown in FIG. 3I, shell structures 5 are grown radially outwards, starting at each one of the vertical surfaces 26. This step may be implemented again using a suitable selective growth method suing either homo-epitaxy, e.g. forming a SiC shell on a SiC core, or hetero-epitaxy, e.g. forming a GaN shell on a SiC core, a diamond shell on a SiC core or a SiC shell on a Si core. Because both the capping element 25 as well as the first dielectric layer comprise a growth inhibiting material, the shell structures 5 are only grown on the vertical surfaces 26, but not on top of the first dielectric layer 21 covering the substrate 1 or on the top or sides of the capping elements 25. In the described embodiment, n-type SiC material is used to grow the shell structure 5, thereby completing a plurality of superjunction structures 3, comprising the p-type core structures 4 and the n-type shell structures 5.

In the situation depicted in FIG. 3J, the capping elements 25 have been removed, for example by selective etching.

FIG. 3K shows the situation after implanting of a channel area 7 in the shell structures 5. For this purpose, ions of a suitable species of the first conductivity type are implanted from the top surface of the superjunction structures 3. This is indicated by the dotted arrows shown in FIG. 3K. Suitable species for p-type implantation comprise, for example, Al and B. Attention is drawn to the fact that the additional charge carriers implanted by means of ion implantation do not significantly affect the electrical properties of the core structures 4. However, they do overcompensate the charge concentration in the shell structure 5 to change it from an n-type semiconductor material to a p-type semiconductor material.

In a subsequent processing state shown in FIG. 3L, a third dielectric layer 27 is formed and may be planarized. In the depicted embodiment, a suitable dielectric layer is deposited in the areas between the individual superjunction structures 3. The third dielectric layer 27 may essentially consist of SiOₓ, in particular SiO₂, SiN or Al₂O₃. It may be the same material as the material of the second dielectric layer 22. The third dielectric layer 27 serves as a base for the gate electrode to be formed later and corresponds to the second sublayer 2b of the embodiment shown in FIG. 1.

Gate insulation structures 9 may be formed, for example by selective oxidation of or controlled deposition of dielectric material on the exposed part of the vertical surface 26 of the shell structure 5.

In a further processing stage shown in FIG. 3M, a metal material has been deposited and optionally planarized on the top surface of the third dielectric layer 27 to form gate structures 8. In the described embodiment, the gate structure 8 essentially covers the entire surface of the third dielectric layer 27 thereby forming a gate-all around-structure 14 as shown in FIG. 2.

In the situation depicted in FIG. 3N, the upper surface of the gate structure 8 has been covered by a fourth dielectric layer 28 corresponding to the third sublayer 2c of FIG. 1. Together with the third dielectric layer 27 and the gate insulation 9, this completes the insulation of the gate structure 8.

Thereafter, as also shown in FIG. 3N, a source electrode 12 may be formed on the planarized top surface of the device under manufacturing. Equally, a drain electrode 11 may be formed on the opposite main surface of the substrate 1, i.e. on the backside of the lower sublayer 1b (not shown in FIG. 3N).

FIG. 4 shows a method 30 for manufacturing a superjunction power semiconductor device comprising steps S31 to S35.

In a step S31, a growth substrate, such as the substrate 1 comprising sublayers 1a and 1b, is provided.

In a step S32, a plurality of vertical growth masks 23 are formed on the growth substrate 1. This may be achieved by the method steps as detailed above with regard to FIGS. 3A to 3d or may be alternatively implemented using additive manufacturing techniques.

In a step S33, a first semiconductor material is selectively grown in the plurality of vertical growth masks to form a corresponding plurality of core structures in a direction perpendicular to a main surface of the growth substrate. This may be implemented, as discussed above with respect to FIGS. 3E and 3F, one or more selective growth steps. For example, at first an n-type plug structure 6 may be formed followed by a p-type main portion 4a of a core structure.

In a step S34, the plurality of vertical growth masks are at least partially removed, thereby exposing vertical surfaces of the plurality of core structures. This may be achieved, for example, by the selective etching method as described above with respect to FIGS. 3G and 3H, or by other suitable methods, such as controlling the length of an etching step to achieve a desired depth of material removal.

In a step S35, a second semiconductor material, such as an n-type semiconductor material, is selectively grown on the previously exposed vertical surfaces of the plurality of core structures to form a plurality of shell structures surrounding the respective core structures. This effectively creates a plurality of superjunction structure. As described above with regard to FIG. 3I, selective growth may be restricted to desired surfaces by covering other surfaces with a dielectric material. Alternatively, the second semiconductor material may be grown on all surfaces of the device under manufacturing with unnecessary parts of the deposited second semiconductor material being removed later.

Further process steps may follow, for example to create further functional areas within the created superjunction structures and/or metal contact areas as detailed above with respect to FIGS. 3J to 3N.

The novel device architecture and manufacturing methods have been described with regard to a superjunction power semiconductor device. However, use of the described architecture and manufacturing method is not restricted to power semiconductor devices, but may also be employed in other regular, cell-based, very dense semiconductor devices.

Such devices may include photovoltaic cells and sensor arrangements, such as image sensors, as well as other optical devices, such as matrix displays.

Attention is drawn to the fact that the embodiments shown in FIGS. 1 to 4 as stated represent exemplary embodiments of the improved device structure and methods for its implementation only. They do not constitute a complete list of all embodiments according to the improved device and method. Actual devices and manufacturing methods may vary from the described embodiments in terms of materials used, processing steps and parameters, dimensions and circuit configurations for example.

### REFERENCE SIGNS

1 substrate
1a, 1b sublayer (of the substrate)
2 dielectric layer
2a to 2c sublayer (of the dielectric layer)
3 superjunction structure
4 core structure
4a main portion (of the core structure)
5 shell structure
6 plug structure
7 channel area
8 gate structure
9 gate insulation
10 cell
11 drain electrode
12 source electrode
13 (first) opening
15 metal layer
16 termination area
17 gate runner
20 power semiconductor device
21 first dielectric layer (growth seed mask layer)
22 second dielectric layer (core structure mask layer)
23 vertical growth mask
24 (second) opening
25 capping element
26 vertical surface
27 third dielectric layer
28 fourth dielectric layer
30 manufacturing method
d pitch distance

1. A superjunction power semiconductor device, comprising:
a substrate;
a plurality of core structures, each core structure having a cylindrical shape extending in a direction perpendicular to a main surface of the substrate and comprising a first semiconductor material of a first conductivity type;
a plurality of annular shell structures, each shell structure surrounding one of the core structures on its outside and comprising a second semiconductor material of a second conductivity type; and
a dielectric layer arranged on the main surface of the substrate,
wherein
the plurality of shell structures surrounding the plurality of core structures are embedded in the dielectric layer;
the dielectric layer comprises at least a first sublayer and a second sublayer;
the first sublayer is arranged between the substrate and the second sublayer and comprises a plurality of passages there between; and
the second sublayer surrounds at least a lower part of each one the plurality of shell structures.

2. The device of claim 1, wherein
the device further comprises a plurality of a plug structures, each plug structure comprising a third semiconductor material of the second conductivity type and arranged in the area of one of the passages so as to contact the main surface of the substrate and a respective one of the shell structures.

3. The device of claim 1, further comprising:
a plurality of channel areas formed in each one of the shell structures, each channel area comprising a fourth semiconductor material of the first conductivity type and being arranged in a control layer of the device; and
at least one gate structure arranged in the control layer, the at least one gate structure being insulated from and surrounding at least a part of each one of the shell structures.

4. The device of claim 3, wherein the at least one gate structure is buried in a dielectric layer.

5. The device of any of claim 1, wherein:
the substrate is one of a silicon, Si, a monocrystalline or polycrystalline silicon carbide, SiC, or a gallium nitride, GaN, semiconductor substrate;
the first semiconductor material comprises a p-type semiconductor material, or a p-type wide bandgap, WBG, semiconductor material; and/or
the second semiconductor material comprises an n-type semiconductor material, an n-type WBG semiconductor material, or an n-type diamond.

6. The device of any one of claim 1, wherein:
the core structures and/or the shell structures extend over a length of 1 to 100 μm in the direction perpendicular to the main surface of the substrate ;
the core structures have a diameter of 25 nm to 5 μm;
the shell structures have a thickness of 0.1 to 5 μm; and/or
the plurality of core structures is arranged in a regular pattern with a pitch distance of less than 1 μm and/or in the range of 1.1 to 2.5 times of the total diameter of one of the core structures surrounded by one of the shell structures.

7. The device of claim 1, further comprising at least one of the following:
a drain electrode formed on second main surface of the substrate;
a source electrode formed on a dielectric layer, and interconnecting an upper end of each one of the plurality of core structures; and/or
a gate electrode electrically connected to at least one gate structure.

8. The device of claim 1, wherein the plurality of core structures and/or shell structures are electrically connected in parallel to form a multi-cell field effect transistor, FET, a metal-insulator-semiconductor field-effect transistor, MISFET, a metal-oxide-semiconductor field-effect transistor, MOSFET, an insulated gate bipolar transistor, IGBT, and/or a junction-gate field-effect transistor, JFET.

9. A method for manufacturing a superjunction power semiconductor device, comprising:
providing a growth substrate;
forming a plurality of vertical growth masks on the growth substrate;
selectively growing a first semiconductor material in the plurality of vertical growth masks to form a corresponding plurality of core structures in a direction perpendicular to a main surface of the growth substrate;
at least partially removing the plurality of vertical growth masks thereby exposing vertical surfaces of the plurality of core structures; and
selectively growing a second semiconductor material on the vertical surfaces of the plurality of core structures to form a corresponding plurality of shell structures surrounding the respective core structures;
wherein forming the plurality of vertical growth masks comprises:
forming a growth seed mask layer with a plurality of first openings, the first openings having a distance corresponding to a pitch distance between the plurality of core structures; and
forming a core structure mask layer with a plurality of second openings, each second opening being arranged in an area corresponding to the respective first opening and being wider than the respective first opening.

10. The method of claim 9, wherein forming the plurality of core structures comprises:
forming a plurality of plug structures by selectively growing a third semiconductor material comprising impurities of a first conductivity type directly on the growth substrate in the plurality of vertical growth masks; and
thereafter, forming a main portion of the plurality of core structures by selectively growing the first semiconductor material comprising impurities of a second conductivity type in the plurality of vertical growth masks.

11. The method of claim 9, wherein forming the plurality of shell structures comprises:
covering a top surface of the plurality of core structures with a growth inhibiting material;
removing an upper part of the plurality of vertical growth masks, such that a remaining, lower part of the plurality of vertical growth masks covers the growth substrate ; and
thereafter, forming the plurality of shell structures by selectively growing the second semiconductor material comprising impurities of the first conductivity type in a radial direction.

12. The method of claim 9, further comprising:
implanting a dopant species into a control layer of the device to form a channel area in each one of the plurality of shell structures;
electrically insulating an outer surface of each one of the shell structures at least in an area corresponding to the channel area; and
forming at least one gate structure within the control layer, the gate structure surrounding the insulated channel areas of the plurality of shell structures.

13. The method of claim 9, further comprising at least one of:
depositing a first conductive layer on a second main surface of the growth substrate to form a common drain electrode for the device;
depositing a second conductive layer on a planarized first dielectric layer surrounding a lower part of the plurality of shell structures to provide a common gate structure for the device; and/or
depositing a third conductive layer on a top surface of a second dielectric layer to form a common source electrode for the device.

14-15. (canceled)
